(19) United States
(12) Patent Application Publication
(10) Pub. No.: US 2025/0143029 A1
(43) Pub. Date: May 1, 2025

(54) LIGHT-EMITTING DIODE AND LIGHT-EMITTING DEVICE

(71) Applicant: XIAMEN SAN'AN OPTOELECTRONICS CO., LTD., Xiamen (CN)

(72) Inventors: QING WANG, Xiamen (CN); LING-YUAN HONG, Xiamen (CN); MINYOU HE, Xiamen (CN); JIANGBIN ZENG, Xiamen (CN); CHAO LU, Xiamen (CN); GUANGYAO WU, Xiamen (CN); CHUNG-YING CHANG, Xiamen (CN)

(21) Appl. No.: 18/919,315

(22) Filed: Oct. 17, 2024

(30) Foreign Application Priority Data
Oct. 31, 2023 (CN) 2023114350141

(51) Int. Cl. H01L 33/46; H01L 33/14; H01L 33/38; H01L 33/62

(52) U.S. Cl. CPC H10H 20/841; H10H 20/8162; H10H 20/8312; H10H 20/857

(57) ABSTRACT

A light-emitting diode and a light-emitting device are provided, relating to the field of semiconductor manufacturing, including a substrate, an epitaxial structure and a Bragg reflective layer. The Bragg reflective layer includes a first film stack and a second film stack alternately and repetitively arranged. The first film stack and the second film stack both include a first material layer with a first refractive index and a second material layer with a second refractive index, the first material layer and the second material layer are alternately stacked repeatedly, and the first refractive index is lower than the second refractive index. In the first film stack, an optical thickness of the first material layer is greater than that of the second material layer. In the second film stack, an optical thickness of the first material layer is less than that of the second material layer.

### CROSS-REFERENCE TO RELATED APPLICATION

This application claims priority to Chinese Patent Application No. 202311435014.1, filed on Oct. 31, 2023. The entire contents of the above-mentioned application are incorporated herein by reference.

### TECHNICAL FIELD

The disclosure relates to the field of semiconductor manufacturing technologies, and more particularly to a light-emitting diode and a light-emitting device.

### BACKGROUND

Light-emitting diode (LED) is a semiconductor light-emitting element, usually made of semiconductors such as gallium nitride (GaN), gallium arsenide (GaAs), gallium phosphide (GaP), gallium arsenide phosphide (GaAsP), etc., and its core is a PN junction with light-emitting characteristics. The LED has the advantages of high luminous intensity, high efficiency, small size and long service life, and is considered as one of the most promising light sources at present. The LED has been widely used in lighting, surveillance and command, high-definition broadcast, premium cinema, office display, conference interaction, virtual reality and other fields.

Distributed Bragg reflector mirror (DBR) is an essential process in the LED, and the quality of the DBR directly affects the brightness of the LED. Therefore, how to continuously optimize the DBR to improve the brightness of the LED is an urgent technical problem that needs to be addressed.

### SUMMARY

The disclosure provides a light-emitting diode, which solves at least one technical problem in that background. Specifically, the disclosure provides a light-emitting diode, which includes a substrate, an epitaxial structure and a Bragg reflective layer. The epitaxial structure includes an active layer. The Bragg reflective layer is located on a side of the epitaxial structure facing away from the substrate.

The Bragg reflective layer includes a first film stack and a second film stack alternately and repetitively arranged. The first film stack and the second film stack both include a first material layer with a first refractive index and a second material layer with a second refractive index, the first material layer and the second material layer are alternately stacked repeatedly, and the first refractive index is less than the second refractive index. In the first film stack, an optical thickness of the first material layer is greater than that of the second material layer. In the second film stack, an optical thickness of the first material layer is less than that of the second material layer.

The disclosure also provides a light-emitting device, which adopts the light-emitting diode provided by any of the above embodiment.

The light-emitting diode provided in the embodiment of the disclosure can greatly improve the overall reflectivity of the structure of the Bragg reflective layer in the light-emitting diode by arranging the Bragg reflective layer about the first film stack and the second film stack. It not only has high reflectivity for light from the active layer in a direction close to a right angle (i.e., light with a small incident angle), but also shows good reflectivity for light in a direction deviating from the right angle (i.e., light with a large incident angle), so as to improve the overall brightness of the light-emitting diode.

### BRIEF DESCRIPTION OF DRAWINGS

FIG. 1 illustrates a schematic cross-sectional view of a light-emitting diode according to an embodiment of the disclosure.

FIG. 2 illustrates a schematic cross-sectional view of a light-emitting diode according to another embodiment of the disclosure.

FIG. 3 illustrates a schematic structural diagram of a stacked structure of a Bragg reflective layer according to an embodiment of the disclosure.

FIG. 4 illustrates a reflectivity view of different stacked orders of the Bragg reflective layer.

FIG. 5 illustrates a schematic diagram of a stacked order of the Bragg reflective layer according to an embodiment of the disclosure.

### DESCRIPTION OF REFERENCE SIGNS

10—epitaxial structure; 11—first semiconductor layer; 12—active layer; 13—second semiconductor layer; 21—first material layer; 22—second material layer; 30—protective layer; 40—substrate; 51—first contact electrode; 52—second contact electrode; 53—first connection electrode; 54—second connection electrode; 60—Bragg reflective layer; 61—first pad electrode; 62—second pad electrode; 70—transparent conductive layer; 80—current blocking layer; 90—insulation layer.

### DETAILED DESCRIPTION OF EMBODIMENTS

An embodiment of the disclosure provides a light-emitting diode, which includes a substrate 40, an epitaxial structure 10 and a Bragg reflective layer 60. The epitaxial structure 10 includes an active layer 12. The Bragg reflective layer 60 is located on a side of the epitaxial structure 10 facing away from the substrate 40.

The Bragg reflective layer 60 includes a first film stack and a second film stack which are alternately and repetitively arranged. The first film stack and the second film stack both include a first material layer 21 with a first refractive index and a second material layer 22 with a second refractive index, the first material layer 21 and the second material layer 22 are alternately stacked repeatedly, and the first refractive index is less than the second refractive index. In the first film stack, an optical thickness of the first material layer 21 is greater than that of the second material layer 22. In the second film stack, an optical thickness of the first material layer 21 is less than that of the second material layer 22.

In this embodiment, by arranging the Bragg reflective layer 60 with respect to the first film stack and the second film stack, the reflectivity of the overall structure of the Bragg reflective layer 60 in the light-emitting diode can be greatly improved. It not only has a high reflectivity for light from the active layer 12 in a direction close to a right angle (that is, light with a small incident angle), but also shows good reflectivity for light in a direction deviating from the right angle (that is, light with a large incident angle), effectively improving the overall brightness of the light emitting diode.

In an embodiment, the first film stack is greater than or equal to 1 in quantity, and the second film stack is greater than or equal to 1 and less than or equal to 3 in quantity, so as to ensure the reflection effect.

In an embodiment, in the same Bragg reflective layer 60, when the first film stack is multiple in quantity, the multiple first film stacks have same or different layers; and when the second film stack is multiple in quantity, the multiple second film stacks have same or different layers, which can be specifically selected according to actual requirements and is not limited herein.

In an embodiment, a total number of layers contained in the first film stack is greater than that contained in the second film stack.

In an embodiment, the number of the layers contained in the first film stack is greater than or equal to 2, and the number of the layers contained in the second film stack is greater than or equal to 2, so as to further improve the reflectivity.

In an embodiment, the first film stack is greater than or equal to the second film stack in quantity.

In an embodiment, in the Bragg reflective layer 60, the material layer closest to the epitaxial structure 10 is the second material layer 22, which can prevent the chip from edge chipping and corner chipping when the chip is cut.

In an embodiment, a material of the first material layer 21 is silicon oxide, and a material of the second material layer 22 is titanium oxide.

In an embodiment, a sum of the number of pairs of layers of all the first film stacks and the number of pairs of layers of all the second film stacks is in a range of 15 pairs and 30 pairs, so as to more effectively improve the reflectivity near the Brewster's angle.

In an embodiment, the light-emitting diode further includes a protective layer 30, the protective layer 30 is located between the epitaxial structure 10 and the Bragg reflective layer 60, and the protective layer 30 is made of a low refractive index material. An optical thickness of the protective layer 30 is greater than a thickness of any single material layer in the Bragg reflective layer 60, which can not only protect the epitaxial structure 10 of the light-emitting diode, but also improve the total reflection effect.

In an embodiment, a material of the protective layer 30 is silicon oxide, which has a low refractive index and can reduce the light absorption.

In an embodiment, an optical thickness of the protective layer 30 is in a range of 588 nanometers (nm) to 1470 nm.

In an embodiment, the optical thickness of each first material layer 21 is λ₁/4, where λ₁ is greater than or equal to 350 nm and less than or equal to 1500 nm, which ensures the stability of coating on the first material layer 21.

In an embodiment, the optical thickness of each layer of the second material layer 22 is λ₂/4, where λ₂ is greater than or equal to 350 nm and less than or equal to 880 nm, λ₂ is less than or equal to 750 nm, so as to ensure the stability of coating on the second material layer 22 and also to make the optical thickness cover the visible light region.

In an embodiment, a thickness of the Bragg reflective layer 60 is in a range of 3 micrometers (μm) to 6 μm.

In an embodiment, a light-emitting wavelength of the light-emitting diode is in a range of 420 nm and 480 nm.

In an embodiment, the epitaxial structure 10 further includes a first semiconductor layer 11 and a second semiconductor layer 13 stacked on two sides of the active layer 12, respectively. The first semiconductor layer 11 is close to the substrate 40.

In an embodiment, the light-emitting diode further includes a first contact electrode 51, a second contact electrode 52, a first connection electrode 53, a second connection electrode 54, an insulation layer 90, a first pad electrode 61, and a second pad electrode 62. The first contact electrode 51 is located on the first semiconductor layer 11 and electrically connected to the first semiconductor layer 11. The second contact electrode 52 is located on the second semiconductor layer 13 and electrically connected to the second semiconductor layer 13. The first connection electrode 53 is located on the Bragg reflective layer 60 and electrically connected to the first contact electrode 51. The second connection electrode 54 is located on the Bragg reflective layer 60 and electrically connected to the second contact electrode 52. The insulation layer 90 covers at least a part of the Bragg reflective layer 60. The first pad electrode 61 is located on the first connection electrode 53 and electrically connected to the first connection electrode 53. The second pad electrode 62 is located on the second connection electrode 54 and electrically connected to the second connection electrode 54.

In an embodiment, the light-emitting diode further includes a transparent conductive layer 70 and a current blocking layer 80. The transparent conductive layer 70 is located between the second contact electrode 52 and the epitaxial structure 10. The current blocking layer 80 is located in the transparent conductive layer 70. Through the above arrangement, the structural reliability can be further ensured and the brightness of the light-emitting diode can be improved.

The disclosure also provides a light-emitting device, and the light-emitting device adopts the light-emitting diode in any of the above embodiments, so that the performance of the light-emitting device can be effectively improved.

In the following, the technical solution of the disclosure will be described through various specific embodiments with reference to the attached drawings in the embodiments of the disclosure.

FIG. 1 is a cross-sectional view of a light-emitting diode according to an embodiment of the disclosure. In order to achieve at least one of the advantages or other advantages, an embodiment of the disclosure provides a light-emitting diode. As shown in the FIG. 1, the light-emitting diode includes a substrate 40, an epitaxial structure 10 and a Bragg reflective layer 60.

Specifically, the epitaxial structure 10 is arranged on an upper surface of the substrate 40. The substrate 40 can be a transparent substrate, an opaque substrate, or a semi-transparent substrate, where the transparent substrate or the semi-transparent substrate can allow the light emitted from the active layer 12 to pass through the substrate 40. For example, the substrate 40 can be any one of a sapphire planar substrate, a sapphire patterned substrate, a silicon substrate, a silicon carbide substrate, a gallium nitride substrate and a glass substrate. In some embodiments, the substrate 40 may be a combined patterned substrate. In other embodiments, the substrate 40 may be thinned or removed to form a thin-film chip.

The epitaxial structure 10 includes a first semiconductor layer 11, an active layer 12, and a second semiconductor layer 13 sequentially stacked in that order. The first semiconductor layer 11 is formed on the substrate 40, and as a layer grown on the substrate 40, the first semiconductor layer 11 can be a gallium nitride semiconductor layer doped with n-type impurities, such as silicon (Si). In some embodiments, a buffer layer may also be disposed between the first semiconductor layer 11 and the substrate 40. In other embodiments, the first semiconductor layer 11 may also be connected to the substrate 40 through an adhesive layer.

The active layer 12 may be a quantum well structure (QW). In some embodiments, the active layer 12 may also be a multiple quantum well structure (MQW), wherein the MQW includes multiple quantum well layers (Well) and multiple quantum barrier layers (Barrier) alternately and repetitively arranged. In addition, the composition and thickness of the well layer in the active layer 12 determine the wavelength of the generated light. In particular, by adjusting the composition of the well layer, the active layer 12 that generates different colors of light such as ultraviolet light, blue light, green light and yellow light can be provided. In this embodiment, the light-emitting wavelength range of the light-emitting diode is 420-480 nm.

The second semiconductor layer 13 may be a gallium nitride-based semiconductor layer doped with p-type impurities such as magnesium (Mg). Although the first semiconductor layer 11 and the second semiconductor layer 13 can each be a single-layer structure, the disclosure is not limited to this and can also be a multi-layer structure, including a superlattice layer. In addition, in other embodiments, when the first semiconductor layer 11 is doped with p-type impurities, the second semiconductor layer 13 may be doped with n-type impurities, that is, the first semiconductor layer 11 is a P-type semiconductor layer and the second semiconductor layer 13 is an N-type semiconductor layer.

Of course, the epitaxial structure 10 can also include other layer materials, such as a window layer or an ohmic contact layer, which can be set as different multilayers according to different doping concentrations or component contents.

Further, the Bragg reflective layer 60 is disposed on a side of the epitaxial structure 10 facing away from the substrate 40, and includes a first film stack and a second film stack alternately and repetitively arranged. In an embodiment, the thickness of the Bragg reflective layer 60 is in a range of 3 μm to 6 μm. The number of the first film stack is greater than or equal to 1, the number of the second film stack is greater than or equal to 1 and less than or equal to 3, and the specific number can be designed according to the actual demand, which is not limited herein. Since the Bragg reflective layer 60 will have reflective electrodes, an optical double resonance (ODR) effect will be formed in the light-emitting diode. Therefore, when the number of the second film stack is less than or equal to 3, an optimal reflection effect can be formed. In this embodiment, the first film stack is greater than or equal to the second film stack in quantity, for example, the number of the first film stacks is 2 and the number of the second film stack is 1.

The first film stack and the second film stack both include a first material layer 21 with a first refractive index and a second material layer 22 with a second refractive index, and the first material layer 21 and the second material layer 22 are alternately stacked repeatedly, with the first refractive index being less than the second refractive index. The terms “high refractive index” and “low refractive index” are used to indicate the difference between the refractive index of the first material layer 21 and the refractive index of the second material layer 22. That is, the first material layer 21 with low refractive index has a lower refractive index than the second material layer 22 with high refractive index. In this embodiment, the first material layer 21 is silicon oxide and the second material layer 22 is titanium oxide. For example, silicon oxide may have a refractive index of about 1.47 at 450 nm, and titanium oxide may have a refractive index of about 2.55 at 450 nm. It should be understood that the first material layer 21 and the second material layer 22 are not limited to silicon oxide and titanium oxide, for example, the first material layer 21 may also be fluoride. As long as the first material layer 21 and the second material layer 22 have different refractive indices and are optically transparent, they are suitable. Here, for instance, dielectric layers such as silicon oxide (SiO₂) and titanium oxide (TiO₂) are more appropriate due to their high transparency, case of deposition, and relatively large refractive index difference.

In this embodiment, the optical thickness of each first material layer 21 is λ₁/4, where λ₁ is greater than or equal to 350 nm and less than or equal to 1500 nm, so as to ensure the stability of the coating on the first material layer 21. The optical thickness of each second material layer 22 is λ₂/4, where λ₂ is greater than or equal to 350 nm and less than or equal to 880 nm, so as to avoid the thickness being too small and affecting the stability of the coating on the second material layer 22, while also ensuring that the optical thickness covers the entire visible light region.

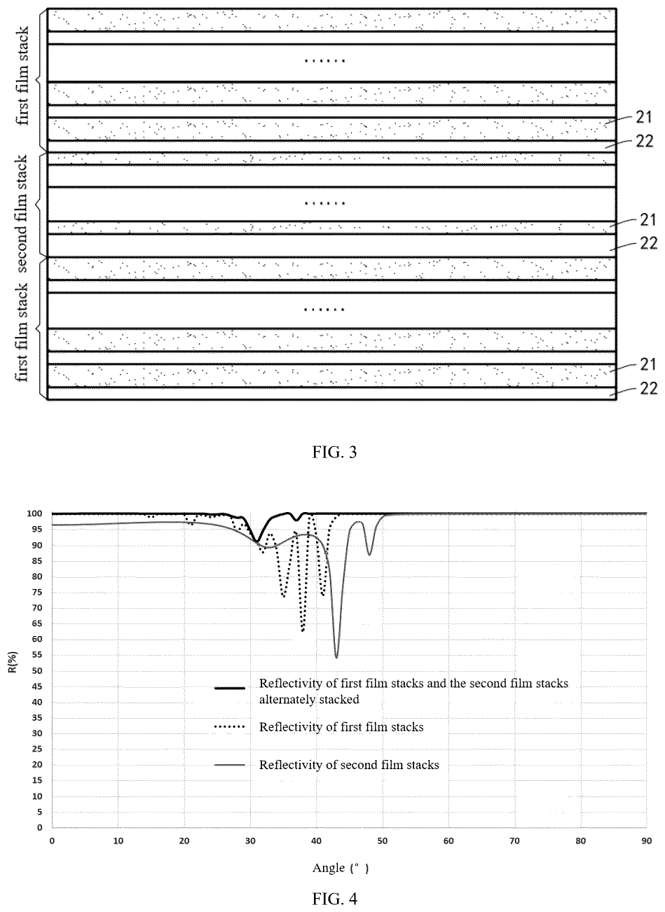

Referring to FIG. 3, in the first film stack, the optical thickness of the first material layer 21 is greater than that of the second material layer 22. Since the refractive index of the first material layer 21 is lower than that of the second material layer 22, the light absorption rate is lower than that of the second material layer 22. Therefore, by designing the first film stack as described above, the light absorption rate of the whole structure of the Bragg reflective layer 60 can be greatly reduced, and the reflectivity near Brewster's angle can also be increased, specifically, the internal reflectivity of the light-emitting diode with the incident angle in the range of 40°-50° can be effectively improved.

Referring to FIG. 3, in the second film stack, the optical thickness of the first material layer 21 is less than that of the second material layer 22. Through the design of the second film stack, the reflectivity near Brewster's angle can be increased, specifically, the internal reflectivity of the light-emitting diode with the incident angle in the range of 30°-40° can be effectively improved.

It should be noted that the stacking mode in FIG. 3 is only one implementation, and the number of the first film stacks and the second film stacks and the number of the first material layers 21 and the second material layers 22 can be adjusted and changed according to actual needs, and are not limited to the number shown in FIG. 3.

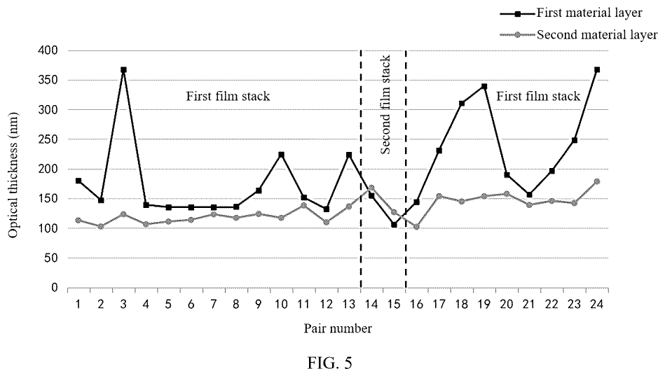

In order to verify the light-emitting effect of the light-emitting diode with the Bragg reflective layer 60, FIG. 4 can be referred, FIG. 4 is a curve chart showing variation of the internal reflectivity of a chip with angle for different stacking modes of the Bragg reflector layer 60. FIG. 4 provides a comparison of the internal reflectivity change of the chip formed by the Bragg reflector layer 60 using a stacking mode of only stacking the first film stack, the internal reflectivity change of the chip formed by the Bragg reflector layer 60 using a stacking mode of only stacking the second film stack, and the internal reflectivity change of the chip formed by the Bragg reflector layer 60 using a stacking mode of alternately and repeatedly stacking the first film stacks and the second film stacks provided by the embodiment of the disclosure. It can be seen that in the arrangement of material layers with different optical thicknesses, the structure in which the first film stack and the second film stack are alternately arranged can improve the reflection characteristics. According to FIG. 4, at an incidence angle of 30° to 40°, the reflectivity using the stacking mode of alternately and repeatedly stacking the first film stacks and the second film stacks is significantly higher than the reflectivity using only the first film stack or only the second film stack, and is close to 100%; at an incidence angle of 40° to 50°, the reflectivity using the stacking mode of alternately and repeatedly stacking the first film stacks and the second film stacks is significantly higher than the reflectivity using only the first film stack or only the second film stack, and is close to 100%. Therefore, the stacking mode of the Bragg reflective layer 60 provided by the embodiment of the disclosure can greatly improve the reflectivity of the incident angles of 30° to 40° and 40° to 50°, thereby effectively improving the light-emitting efficiency of the whole light-emitting diode.

In an embodiment, in the Bragg reflective layer 60, the material layer closest to the epitaxial structure is the second material layer 22, which can prevent the chip from edge chipping and corner chipping when the chip is cut. In addition, the material layer farthest from the epitaxial structure is the first material layer 21, which ensures insulation and adhesion to the rear electrode.

In a specific embodiment, in the same Bragg reflective layer 60, multiple first film stacks contain the same or different layers, for example, each first film stack may have the same 10 layers, or some first film stacks may have 8 layers and some first film stacks may have 10 layers. Similarly, multiple second film stacks contain the same or different layers. The specific arrangement can be selected according to the actual needs, which is not limited herein.

Due to the fact that the second film stack is designed with fewer layers to enhance the reflectivity at incidence angles of 30° to 40°, the total number of layers contained in the first film stack is greater than that contained in the second film stack. Specifically, the number of layers contained in the first film stack is greater than or equal to 2, and the number of layers contained in the second film stack is greater than or equal to 2. That is, the first film stack has at least one first material layer 21 and one second material layer 22, and the second film stack has at least one first material layer 21 and one second material layer 22. The specific number of layers of each film stack can be adjusted according to actual needs, and this embodiment is not limited to this.

In an alternative embodiment, a sum of the number of pairs of layers of all the first film stacks and the number of pairs of layers of all the second film stacks is in a range of 15 pairs and 30 pairs. Specifically, no matter how the stacking mode of the first film stack and the second film stack changes, the reflectivity of the Bragg reflective layer 60 will increase with the increase of the number of stacked layers. Therefore, the number of stacked pairs of layers should be as many as possible, and this embodiment is specifically in a range of 15 pairs to 30 pairs, so as to more effectively improve the reflectivity near Brewster's angle.

In some exemplary embodiments, the light-emitting diode further includes a protective layer 30, the protective layer 30 is located between the epitaxial structure 10 and the Bragg reflective layer 60, and the protective layer 30 is a low refractive index material. The optical thickness of the protective layer 30 is greater than that of other material layers in the Bragg reflective layer 60, which can protect the epitaxial structure 10 of the light-emitting diode. The material of the protective layer can be silicon oxide, which has a low refractive index and can reduce light absorption. Specifically, the optical thickness of the protective layer 30 can be in a range of 588 nm to 1470 nm to further enhance the reflection and improve the total reflection effect.

Taking FIG. 5 as an example, this embodiment provides 2 a Bragg reflector layer 60 composed of 24 pairs of alternating layers, each pair consisting of one layer of the first material layer 21 (e.g., SiO₂) and one layer of the second material layer 22 (e.g., TiO₂), where the number of first film stacks is 2 and the number of second film stack is 1. Specifically, the numbers 1 to 13 represent an example where the first film stack has an optical thickness stacked with 13 pairs of layers, the numbers 14 and 15 represent an example where the second film stack has an optical thickness stacked with 2 pairs of layers, and the numbers 16 to 24 represent an example where the other first film stack has an optical thickness stacked with 9 pairs of layers. In this embodiment, the number of layers contained in multiple first film stacks is different from that contained in multiple second film stacks, and the total number of layers contained in the first film stacks is greater than that contained in the second film stacks.

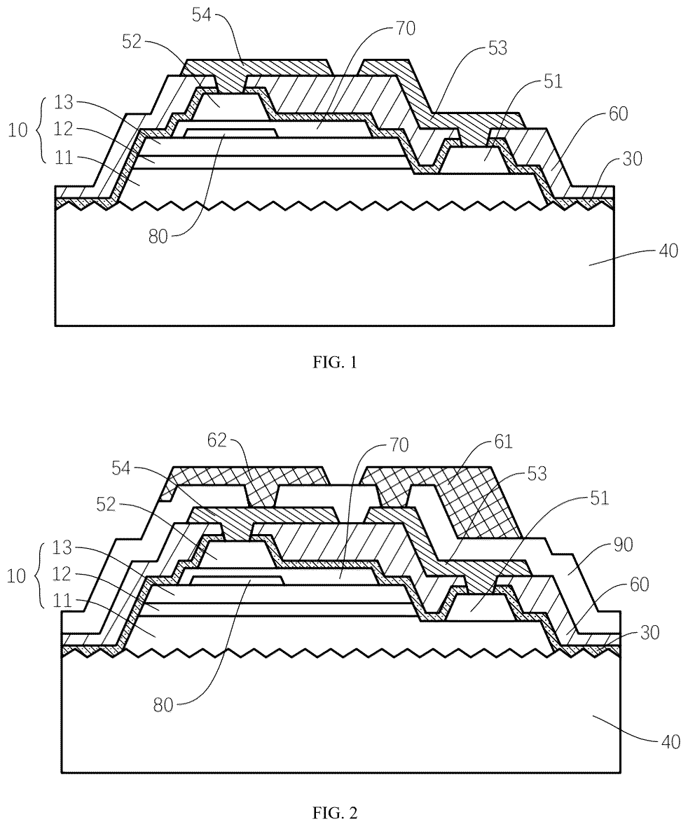

Further, referring to FIGS. 1 and 2, the LED further includes a first contact electrode 51, a second contact electrode 52, a first connection electrode 53, a second connection electrode 54, an insulation layer 90, a first pad electrode 61, and a second pad electrode 62. The first contact electrode 51 is located on the first semiconductor layer 11 and electrically connected to the first semiconductor layer 11. The second contact electrode 52 is located on the second semiconductor layer 13 and electrically connected to the second semiconductor layer 13. The first connection electrode 53 is located on the Bragg reflective layer 60 and electrically connected to the first contact electrode 51. The second connection electrode 54 is located on the Bragg reflective layer 60 and electrically connected to the second contact electrode 52. The insulation layer 90 covers at least a part of the Bragg reflective layer 60. The first pad electrode 61 is located on the first connection electrode 53 and electrically connected to the first connection electrode 53. The second pad electrode 62 is located on the second connection electrode 54 and electrically connected to the second connection electrode 54.

In this embodiment, the first contact electrode 51, the first connection electrode 53, the first pad electrode 61 and the second contact electrode 52, the second connection electrode 54 and the second pad electrode 62 can all be metal electrodes, that is, the metal electrodes are made of metal materials, such as at least one of nickel, gold, chromium, titanium, platinum, palladium, rhodium, iridium, aluminum, tin, indium, tantalum, copper, cobalt, iron, ruthenium, zirconium, tungsten, and molybdenum, or at least one type of alloy or laminated layers selected from the aforementioned materials. For example, the first contact electrode 51, the first connection electrode 53 and the first pad electrode 61 may be N electrodes, and the second contact electrode 52, the second connection electrode 54 and the second pad electrode 62 may be P electrodes.

In this embodiment, the insulation layer 90 covers the part of the Bragg reflective layer 60, which can protect the Bragg reflective layer 60, prevent the Bragg reflective layer 60 from being damaged in the manufacturing process and subsequent use, and also reduce the possibility of short circuit abnormality of the light-emitting diode. The material of the insulation layer 90 includes a non-conductive material. The non-conductive material is specifically an inorganic material or a dielectric material. The inorganic material may include silica gel. The dielectric material includes an electrically insulating material such as aluminum oxide, silicon nitride, silicon oxide, titanium oxide, or magnesium fluoride. For example, the insulation layer 90 may be silicon dioxide, silicon nitride, titanium oxide, tantalum oxide, niobium oxide, barium titanate or a combination thereof.

In other alternative embodiments, the light-emitting diode further includes a transparent conductive layer 70 and a current blocking layer 80. The transparent conductive layer 70 is located between the second electrode 50 and the epitaxial structure 10. The current blocking layer 80 is located in the transparent conductive layer 70.

The current blocking layer 80 is used to block the current, so as to prevent the current from crowding right below the electrode and scattering the current. The transparent conductive layer 70 serves as a channel through which current flows. By this design, when current flows through the transparent conductive layer 70 through the entire surface of the first semiconductor layer 11, current crowding is avoided, and the current is ensured to spread evenly on the surface of the first semiconductor layer 11, so as to improve the luminous efficiency.

As an example, the current blocking layer 80 may be SiO₂, silicon nitride (Si₃N₄), or their composite structures. The material of the transparent conductive layer 70 includes one or more combinations of transparent conductive materials such as indium tin oxide, cadmium tin oxide, antimony oxide (Sb₂O₃) and zinc oxide, zinc gallium oxide, indium oxide, indium-doped zinc oxide, aluminum-doped zinc oxide, gallium-doped zinc oxide, or aluminum-doped indium tin oxide. In this embodiment, the transparent conductive layer 70 is an indium tin oxide semiconductor transparent conductive film (ITO) layer formed by evaporation or sputtering.

An embodiment of the disclosure also provides a light-emitting device, which can use the light-emitting diode of any of the foregoing embodiments to effectively improve the photoelectric performance of the light-emitting device.

What is claimed is:

1. A light-emitting diode, comprising:
a substrate;
an epitaxial structure, comprising an active layer; and
a Bragg reflective layer, located at a side of the epitaxial structure facing away from the substrate;
wherein the Bragg reflective layer comprises a first film stack and a second film stack alternately and repetitively arranged; the first film stack and the second film stack both comprise a first material layer with a first refractive index and a second material layer with a second refractive index, the first material layer and the second material layer are alternately stacked, and the first refractive index is less than the second refractive index;
wherein in the first film stack, an optical thickness of the first material layer is greater than that of the second material layer; and
wherein in the second film stack, an optical thickness of the first material layer is less than that of the second material layer.

2. The light-emitting diode as claimed in claim 1, wherein the first film stack is greater than or equal to 1 in quantity, and the second film stack is greater than or equal to 1 and less than or equal to 3 in quantity.

3. The light-emitting diode as claimed in claim 2, wherein in the Bragg reflective layer, when the first film stack is multiple in quantity, the multiple first film stacks have same or different layers; and when the second film stack is multiple in quantity, the multiple second film stacks have same or different layers.

4. The light-emitting diode as claimed in claim 1, wherein a total number of layers contained in the first film stack is greater than that contained in the second film stack.

5. The light-emitting diode as claimed in claim 1, wherein layers contained in the first film stack are greater than or equal to 2, and layers contained in the second film stack are greater than or equal to 2.

6. The light-emitting diode as claimed in claim 1, wherein the first film stack is greater than or equal to the second film stack in quantity.

7. The light-emitting diode as claimed in claim 1, wherein a material layer in the Bragg reflective layer closest to the epitaxial structure is the second material layer.

8. The light-emitting diode as claimed in claim 1, wherein a material of the first material layer is silicon oxide, and a material of the second material layer is titanium oxide.

9. The light-emitting diode as claimed in claim 1, wherein a sum of a number of pairs of layers of all the first film stack and a number of pairs of layers of all the second film stack is in a range of 15 pairs to 30 pairs.

10. The light-emitting diode as claimed in claim 1, wherein the light-emitting diode further comprises a protective layer, the protective layer is located between the epitaxial structure and the Bragg reflective layer, and the protective layer is made of a low refractive index material; and an optical thickness of the protective layer is greater than a thickness of any single material layer in the Bragg reflective layer.

11. The light-emitting diode as claimed in claim 10, wherein a material of the protective layer is silicon oxide.

12. The light-emitting diode as claimed in claim 10, wherein an optical thickness of the protective layer is in a range of 588 nanometers (nm) to 1470 nm.

13. The light-emitting diode as claimed in claim 1, wherein the optical thickness of each first material layer is λ₁/4, where λ₁ is greater than or equal to 350 nm and less than or equal to 1500 nm.

14. The light-emitting diode as claimed in claim 1, wherein the optical thickness of each second material layer is λ₂/4, where λ₂ is greater than or equal to 350 nm and less than or equal to 880 nm.

15. The light-emitting diode as claimed in claim 1, wherein a thickness of the Bragg reflective layer is in a range of 3 micrometers (μm) to 6 μm.

16. The light-emitting diode as claimed in claim 1, wherein a light-emitting wavelength of the light-emitting diode is in a range of 420 nm and 480 nm.

17. The light-emitting diode as claimed in claim 1, wherein the epitaxial structure further comprises a first semiconductor layer and a second semiconductor layer stacked on two sides of the active layer respectively; and the first semiconductor layer is close to the substrate.

18. The light-emitting diode as claimed in claim 17, wherein the light-emitting diode further comprises:
a first contact electrode, located on the first semiconductor layer and electrically connected to the first semiconductor layer;
a second contact electrode, located on the second semiconductor layer and electrically connected to the second semiconductor layer;
a first connection electrode, located on the Bragg reflective layer and electrically connected to the first contact electrode;
a second connection electrode, located on the Bragg reflective layer and electrically connected to the second contact electrode;
an insulation layer, covering at least a part of the Bragg reflective layer;
a first pad electrode, located on the first connection electrode and electrically connected to the first connection electrode; and
a second pad electrode, located on the second connection electrode and electrically connected to the second connection electrode.

19. The light-emitting diode as claimed in claim 18, wherein the light-emitting diode further comprises:
a transparent conductive layer, located between the second contact electrode and the epitaxial structure; and
a current blocking layer, located in the transparent conductive layer.

20. A light-emitting device, wherein the light-emitting device adopts the light-emitting diode as claimed in claim 1.
